(19) United States
(12) Patent Application Publication
(10) Pub. No.: US 2013/0285259 A1
(43) Pub. Date: Oct. 31, 2013

(54) METHOD AND SYSTEM FOR WAFER AND STRIP LEVEL BATCH DIE ATTACH ASSEMBLY

(71) Applicant: Caleb C. Han, Phoenix, AZ (US)

(72) Inventor: Caleb C. Han, Phoenix, AZ (US)

(21) Appl. No.: 13/460,213

(22) Filed: Apr. 30, 2012

(51) Int. Cl. H01L 23/488; B32B 3/26; H01L 21/78

(52) U.S. Cl. 257/777; 438/113; 428/156; 257/E23.023; 257/E21.599

(57) ABSTRACT

A method and system is provided by which multiple semiconductor die stacks can be assembled in a batch manner, and which also provides for die alignment tolerances required by microelectromechanical systems and other system-in-package applications. The batch process and accuracy is provided, in part, by an intermediate die attach carrier that has multiple die pockets fabricated to hold a set of die with an alignment required for the application. Die are placed in each pocket using a die sorting process. Then a batch process operation is performed in which wafer or strip-level alignment and bonding tools are used to join the die in the intermediate die attach carrier in stacks with a second set of die.

### BACKGROUND

1. Field

This disclosure relates generally to semiconductor packaging, and more specifically, to stacked semiconductor die assembly packaging using batch processing.

2. Related Art

Size and processing needs for modern electronic devices result in placing larger numbers of semiconductor components in progressively smaller areas. One mechanism for addressing these space concerns is to stack semiconductor die within a package, thereby providing additional “real estate” for components in a system-in-a-package (SIP). Additionally, varying types of microelectromechanical systems (MEMS) devices also use stacking processes in order to provide a physically close relationship between a sensor portion of the MEMS device and a signal processing portion of the MEMS device.

Typical processes for assembling stacked die in a package provide for one-by-one placement of a die on another die, using die attach equipment. This process is costly in both time and resources. The die attach process has limited control of die rotation accuracy, which is often not sufficient for certain sensor applications such as accelerometers and magnetometers. In addition, as die geometries get smaller, any lateral placement errors can be a significant percentage of the die size. Thus, the traditional die attach processes cannot meet the tolerances of smaller and more sensitive stacked devices.

It is therefore desirable to have a process by which stacked die in package systems can be manufactured that meets the sensitivity (rotational) and size (lateral) tolerances demanded by today's devices. Further, it is desirable that this process provide these advantages in a less resource and time consuming manner.

### BRIEF DESCRIPTION OF THE DRAWINGS

The present invention may be better understood, and its numerous objects, features, and advantages made apparent to those skilled in the art by referencing the accompanying drawings.

FIG. 1 is a simplified block diagram illustrating a system-in-package (SIP) having a stacked die configuration typical of devices in the prior art.

FIG. 2 is a simplified block diagram illustrating a cross section of a die wafer having a laminated die adhesive layer, usable with embodiments of the present invention.

FIG. 3 is a simplified block diagram illustrating a cross section of die resting in pockets of an intermediate die attach carrier (IDAC), in accord with embodiments of the present invention.

FIG. 4 is a simplified block diagram illustrating a cross section of the system in FIG. 3 at a subsequent stage in the assembly of a stacked semiconductor package, in accord with embodiments of the present invention.

FIG. 5 is a simplified block diagram illustrating a cross section of the system in FIG. 4 at a subsequent stage in the assembly of the stacked semiconductor package, in accord with embodiments of the present invention.

FIG. 6 is a simplified block diagram illustrating a cross-section of a stacked semiconductor structure resulting from the system in FIG. 5, in accord with embodiments of the present invention.

FIG. 7 is a simplified block diagram illustrating an example of the use of one of the singulated stacked semiconductor structures of FIG. 6, at a further stage in assembly.

FIG. 8 is a simplified block diagram of a cross section of a singulated system-in-package formed in accord with embodiments of the present invention.

FIG. 9 is a simplified block diagram illustrating a cross section of an IDAC in a stage of formation, in accord with embodiments of the present invention.

FIG. 10 is a simplified block diagram illustrating a cross section of the IDAC at a stage in formation subsequent to that of FIG. 9, in accord with embodiments of the present invention.

FIG. 11 is a top view of the IDAC, as formed in accord with embodiments of the present invention.

FIG. 12 is a simplified block diagram of a cross-section of a strip chuck version of the IDAC, in accord with an alternate embodiment of the present invention.

FIG. 13 is a simplified block diagram illustrating a cross section of the system of FIG. 12 at a subsequent stage in processing, in accord with embodiments of the present invention.

FIG. 14 is a simplified block diagram illustrating a cross section of system of FIG. 13 at a subsequent stage in processing, in accord with embodiments of the present invention.

FIG. 15 is a simplified block diagram of a cross section of the package substrate with the attached stacked die assemblies upon removal from the strip chuck, in accord with embodiments of the present invention.

FIG. 16 is a simplified block diagram of a cross section of a singulated SIP formed in accord with embodiments of the present invention.

FIG. 17 is a top view of strip chuck IDAC, as formed in accord with embodiments of the present invention.

The use of the same reference symbols in different drawings indicates identical items unless otherwise noted. The figures are not necessarily drawn to scale.

### DETAILED DESCRIPTION

Embodiments of the present invention provide a method and system by which multiple die stacks can be assembled in a batch manner, and which also provides for die alignment tolerances required by MEMS and other SIP applications. The batch process and accuracy is provided, in part, by an intermediate die attach carrier that has multiple die pockets fabricated to hold a set of die with an alignment required for the application. Die are placed in each pocket using a die sorting process. Then a batch process operation is performed in which wafer or strip-level alignment and bonding tools are used to join the die in the intermediate die attach carrier in stacks with a second set of die.

Stacking die in package assemblies has historically been a difficult and expensive process. Many products, including sensor products, require multi-die assembly and high angular accuracy. Current processes for providing stacked die assembly include using conventional die attach equipment in a one die-by-one die process method. Such methods can be slow and can have a high resource cost. In addition, typical die attach equipment can provide only an angular, or rotational, accuracy of greater than +/−2°, which is insufficient for certain sensor applications such as accelerometers and magnetometers. Further, as die size continues to get smaller, lateral die attach accuracy also becomes difficult to control.

FIG. 1 is a simplified block diagram illustrating a system-in-package (SIP) having a stacked die configuration typical of devices in the prior art. SIP 100 includes a bottom die 110 and a top die 120. The nature of the bottom and top die depends on the application for the SIP. For example, in a sensor application, bottom die 110 can be a signal processor and top die 120 can be a MEMS type device (e.g., an accelerometer, a pressure sensor, and the like). Top die 120 is attached to a top surface of bottom die 110 through the use of an adhesive layer 130. Adhesive layer 130 can be a variety of die attach adhesives as appropriate the application, including, but not limited to, dry film type adhesives and pastes.

The stacked die are mounted on a package substrate 140 using a second adhesive layer 150. Package substrate 140 can be a variety of materials, depending upon the nature of the application for the SIP. For example, package substrate 140 can be a laminate substrate such as an epoxy-based laminate or a resin-based laminate, a tape substrate such as polyimide, or a metal lead frame. Second adhesive layer 150 can be a die attach adhesive such as that described for adhesive layer 130, or a eutectic solder bond or an epoxy, as examples, and can be the same as or different than adhesive layer 130.

Additional components can be mounted on the package substrate, but are not included in the figure for sake of clarity.

The top and bottom die can be electrically coupled using, for example, a wire bond 160, and similarly one or both of the top and bottom die can be electrically coupled to contacts on substrate 140 using, for example, a wire bond 170. Alternative methods for electrically coupling the die and the substrate can be used, for example, using metal traces, or printing of conductors, and the like. Electrical contacts from one pad to another or to the substrate are connected by these electrical couplings.

SIP 100 is encapsulated in an encapsulant 180. The molding material forming encapsulant 180 can be any appropriate encapsulant including, for example, silica-filled epoxy molding compounds, plastic encapsulation resins, and other polymeric materials such as silicones, polyimides, phenolics, and polyurethanes. The molding material can be applied by a variety of standard processing techniques used in encapsulation including, for example, printing, pressure molding and spin application.

Embodiments of the present invention avoid the limitations of traditional methods of forming a stacked die package by using an intermediate die attach carrier to hold singulated die in place for attachment with the other of the die used in the stack configuration. In one embodiment, the intermediate die attach carrier can take the form of a wafer-type assembly having pockets for each die to be placed in preparation for assembly. In another embodiment, the intermediate die attach carrier can take the form of a strip chuck having pockets for each die be placed in preparation for assembly. Through the use of an intermediate die attach carrier (IDAC), the relatively slow one die-by-one die assembly process is avoided. Further, dimensional tolerances of the pockets on the IDAC can be defined such that required rotational and lateral accuracy of the stacked die assembly can be met. These embodiments will be discussed in greater detail below.

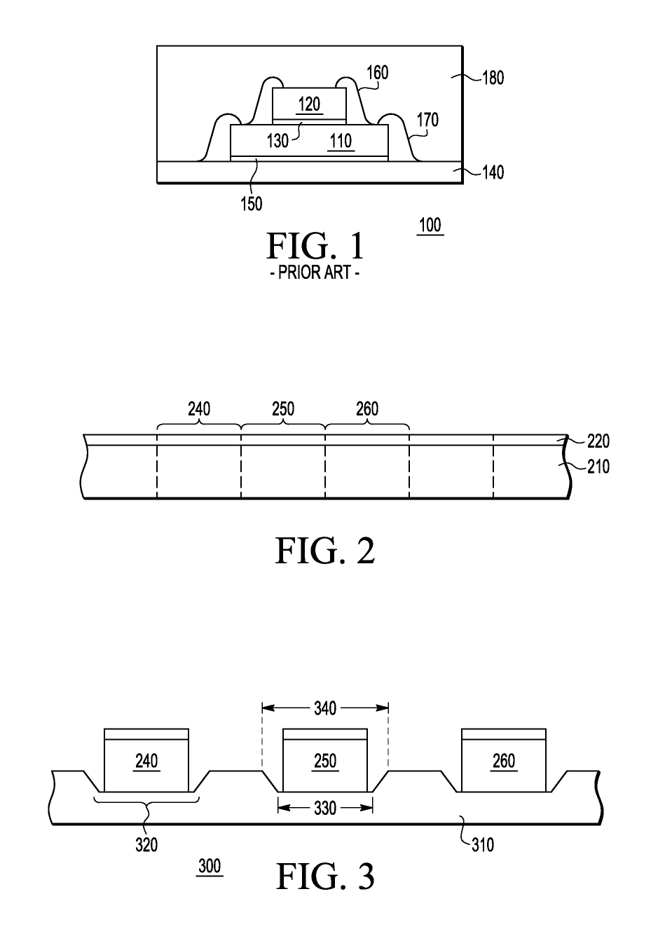

FIG. 2 is a simplified block diagram illustrating a cross section of a die wafer having a laminated die adhesive layer, usable with embodiments of the present invention. Top die wafer 210 is laminated with a die adhesive layer 220, illustrated on top of die wafer 210. As discussed above, the adhesive layer 220 can be a variety of materials, including but not limited to a die attached film or a screen-printed epoxy. The laminated assembly is illustrated with dashed lines 230 indicating the locations where individual die can be singulated from the laminated assembly by sawing. Regions for individual die 240, 250, and 260 are indicated by way of example.

FIG. 3 is a simplified block diagram illustrating a cross section of die resting in pockets of an intermediate die attach carrier, in accord with embodiments of the present invention. In system 300, singulated die 240, 250, and 260 are each shown in a pocket (e.g., 320) of intermediate die attach carrier (IDAC) 310. IDAC 310 is a wafer-type assembly illustrated in greater detail in association with FIGS. 10 and 11, and discussed more fully below. The die pockets on IDAC 310 are fabricated such that a base dimension 330 of the bottom of the pocket is smaller than a corresponding top dimension 340 measured across the opening of the pocket. Further, base dimension 330 is of a length that is equal to or slightly greater than a corresponding dimension of a die to be placed in that pocket (e.g., die 250). By virtue of the dimensions of the base of each pocket being approximately that of the die to be placed in the pocket, along with the sloped sides of the pocket generated by matching the smaller base dimension to the larger top dimension, a die placed in a pocket will be forced into the orientation of that pocket. In one embodiment, the die are placed into the pockets from the singulated top die wafer using a pick and place machine or a high throughput die sorter. Alternatively, the die can be poured in bulk on the IDAC, which can then be vibrated to cause the die to settle in the IDAC pockets. Such agitation can include, for example, an ultrasonic or mechanical vibration.

It is expected that the sloped sides of the pockets will typically allow die placed in the pockets to slide down the sides of the pocket and lie flat in the pocket. In some applications this may not naturally happen. In such cases, the IDAC can be modified to put one or more holes in the bottom of each pocket so that a vacuum system below the IDAC can be used to apply a negative pressure at the bottom of the pockets to force placed die into the bottom of the pockets. These holes can be formed by, for example, deep reactive ion etching (DRIE), laser or mechanical means, as appropriate to the application.

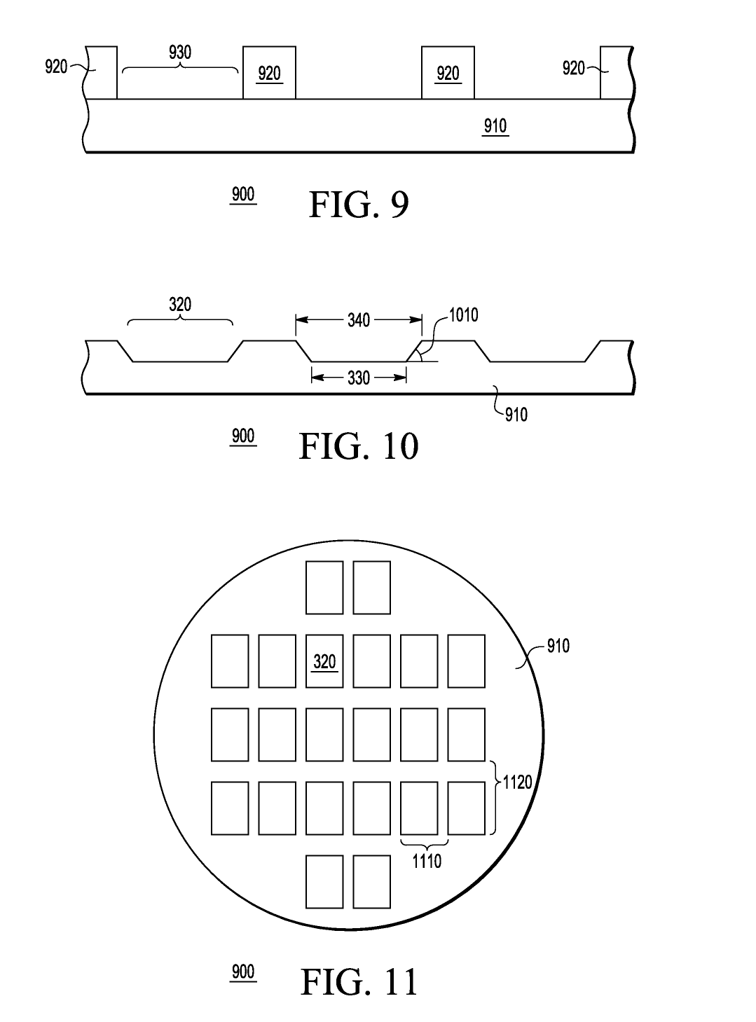

IDAC 310 can be made from a variety of materials. For example, copper or aluminum can be used for the IDAC and the pockets can be formed using highly accurate micro machining to place the pockets in an orientation desired for the application. In a preferred embodiment, IDAC 310 can be made from a silicon wafer. In a silicon wafer IDAC, the pockets can be formed using etching techniques known in the art, and described more fully in association with FIGS. 9 through 11 below.

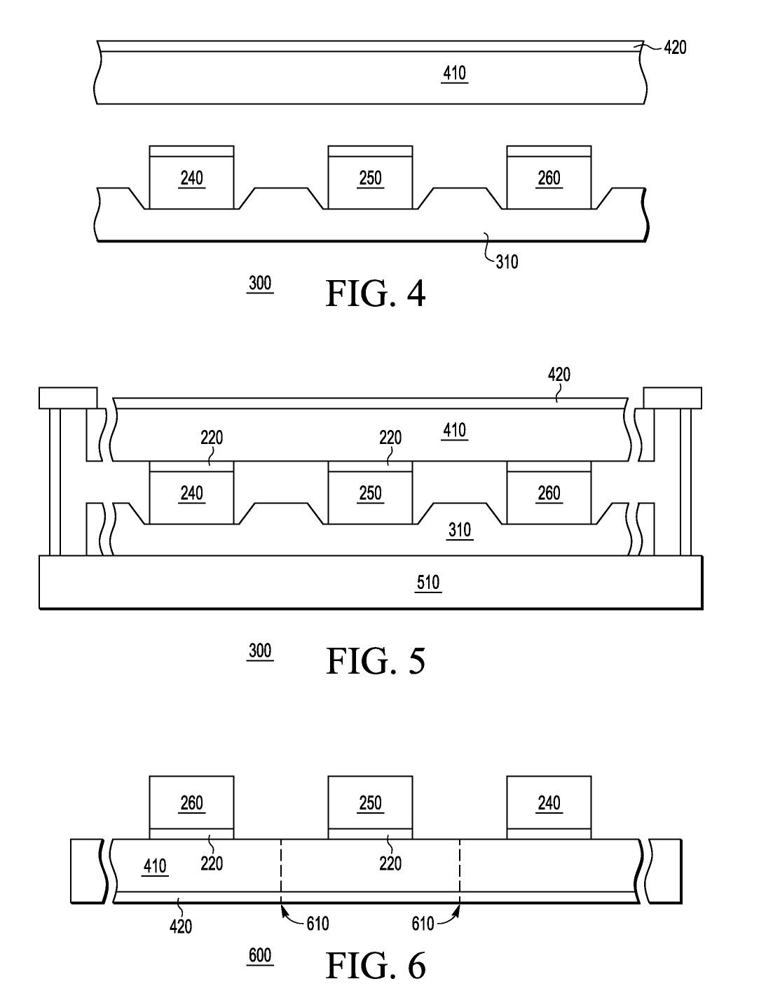

FIG. 4 is a simplified block diagram illustrating a cross section of system 300 at a subsequent stage in the assembly of a stacked semiconductor package, in accord with embodiments of the present invention. As illustrated in FIG. 3, die 240, 250, and 260 are in the IDAC pockets. A second die wafer 410 is provided to be attached to die 240, 250, and 260. In the illustrated embodiment, second die wafer 410 is laminated with a die attach material on the face of the die wafer facing away from die 240, 250, and 260. It should be noted that the die attach material need not be applied at this point and can be applied at a later time without departing from the advantages of the present invention.

FIG. 5 is a simplified block diagram illustrating a cross section of system 300 at a stage in the assembly of the stacked semiconductor package subsequent to that illustrated in FIG. 4, in accord with embodiments of the present invention. In FIG. 5, second die wafer 410 is brought into contact with top die 240, 250, and 260 through the use of a wafer aligner and bonding chuck device 510. Wafer aligner and bonding chuck device 510 can use alignment features on both IDAC 310 and second die wafer 410 to orient the IDAC and second die wafer such that all the die are properly aligned for the stacked die package. Wafer aligner and bonding chuck device 510 bring the top die and second die wafer into contact such that adhesive layer 220 on each of the top die can bond the top die to the second die wafer.

One advantage of the present invention is that standard equipment can be used to aid in implementing the process. Wafer aligner and bonding chuck device 510 is a typical device used in microelectromechanical systems (MEMS) wafer bonding processing that can be used with minimal modifications, if any, to implement the process. Techniques used to align the wafer and IDAC are typical to those used in the art.

Through the use of the illustrated method, each die placed on IDAC 310 can be bonded to the second die wafer at the same time. In some applications, IDAC 310 can provide 17,000 or more die for stacking. By simultaneously attaching and bonding die in this manner, the die-by-die process used in traditional methods, which includes time intensive bonding of each assembly individually, including applying pressure and bonding temperature, is avoided. This can result in a significant time saving over traditional methods, especially as the number of die supported by the IDAC increases.

FIG. 6 is a simplified block diagram illustrating a cross-section of stacked structure 600 resulting from system 300 illustrated in FIG. 5, in accord with embodiments of the present invention. Second die wafer 410 has been removed from wafer aligner and bonding chuck device 510, and rotated to illustrate top die 240, 250, and 260 attached to the illustrated top surface of the second die wafer. FIG. 6 also provides an example of singulation lines 610 at which the bottom die provided by second die wafer 410 can be separated from each other.

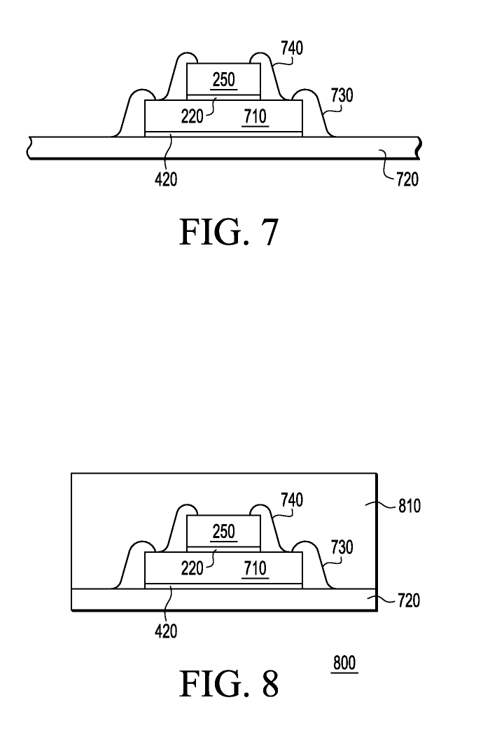

FIG. 7 is a simplified block diagram illustrating an example of the use of one of the singulated stacked die configurations of FIG. 6, at a further stage in assembly. Die 250 is attached to a bottom die 710 formed from the singulation of second die wafer 410 at singulation lines 610. Bottom die 710 is attached to a package substrate 720 through the use of adhesive layer 420. As discussed with regard to FIG. 1, adhesive layer 420 can be a die attach adhesive, a eutectic solder bond, or an epoxy, for example. As with device 100, package substrate 720 can be a laminate substrate such as an epoxy-based laminate or a resin-based laminate, a tape substrate, or a metal lead frame. Contacts (not shown) on a top surface of bottom die 710 are electrically coupled to contacts on a surface of substrate 720 (not shown) using, for example, a wire bond 730. Similarly, contacts (not shown) on a top surface of top die 250 are electrically coupled to contacts of the top surface of bottom die 710 (or contacts on substrate 720) using, for example, a wire bond 740.

The specific configuration of substrate 720, the electrical couplings between bottom die 710 and top die 250, and the nature of the materials used for the adhesive layers and the package substrate, for example, depend upon the nature of the application for the stacked die SIP. For example, a hole through substrate 720 beneath die 710 may be needed for certain applications (e.g., a vent for a pressure sensor). As another example, thermal contacts may be necessary through substrate 720. Further, electrical contacts between the die and the die to the substrate can be formed in a variety of ways that do not depart from the present invention.

FIG. 8 is a simplified block diagram of a cross section of a singulated SIP 800 formed in accord with embodiments of the present invention. A molding compound 810 is applied to the structures affixed to substrate 710 (e.g., die 250, die 710, wire bonds 730 and 740), forming an encapsulant 810 that encapsulated the structures within the molding material and formed a panel. The molding material can be any appropriate encapsulant including, for example, silica-filled epoxy molding compounds, plastic encapsulation resins, and other polymeric materials such as silicones, polyimides, phenolics, and polyurethanes. The molding material can be applied by a variety of standard processing techniques used in encapsulation including, for example, printing, pressure molding and spin application. Once the molding material is applied, the panel can be cured by exposing the materials to certain temperatures for a period of time, or by applying curing agents, or both. FIG. 8 illustrates SIP 800 subsequent to singulation of the encapsulated devices from the panel.

FIG. 9 is a simplified block diagram illustrating a cross section of an IDAC in a stage of formation, in accord with embodiments of the present invention. As discussed above, IDAC 900 (or IDAC 310) can be formed from a silicon wafer 910. A photoresist layer 920 can be deposited on silicon wafer 910. The photoresist layer is patterned through standard techniques to form openings 930 (e.g., by forming an etching mask layer, such as silicon nitride or silicon oxide). Openings 930 dimensionally correspond to the desired pocket top dimensions (e.g., 340).

FIG. 10 is a simplified block diagram illustrating a cross section of IDAC 900 at a subsequent stage in formation from FIG. 9, in accord with embodiments of the present invention. Subsequent to formation of the patterned photoresist layer, etching of silicon wafer 910 is performed to form the pockets. One example of such an etching process is a wet anisotropic etch. The anisotropic etchant is used in combination with an etch stop technique to accurately form the desired pocket dimensions. The anisotropic etchant etches the silicon preferentially along crystal planes. In silicon, the (111) crystal planes are at an angle of 54.74 degrees to the wafer surface. Thus, as a result of the anisotropic etching, the slope of angle 1010 of the pocket walls is 54.74 degrees. By choosing the top dimensions of the pockets (e.g., 340) through patterning of the photoresist, and by timing the period of etching, the bottom dimensions of the pockets (e.g., 330) can be accurately determined. If uniformity of pocket depth is required, then in another embodiment, a silicon-on-insulator (SOI) type wafer can be used. In this embodiment, the insulating layer acts as a vertical etch stop. Thus, the IDAC can be formed using standard silicon processing techniques that also allow for the rotational and lateral accuracy needed for the stacked SIP devices.

FIG. 11 is a top view of IDAC 900, as formed in accord with embodiments of the present invention. Silicon wafer 910 is illustrated with a pattern of pockets 320 formed thereon. The pattern of pockets can be determined through the use of the photolithographic methods discussed above. Depending on the application, the pattern can have differing X pitch 1110 and Y pitch 1120. X and Y pitches can be determined based upon size and spacing of the die formed from second die wafer 410. Again, through the use of a silicon wafer and photolithographic methods, a great deal of flexibility is provided in formation of the IDAC (e.g., number of pockets, relative locations, and the like). It should be understood that the illustration of FIG. 11 is provided only by way of example and that embodiments of the present invention are not limited to the number and configuration of the IDAC pockets.

While significant flexibility is provided through the use of a wafer IDAC, certain configurations of stacked die cannot be formed using a wafer IDAC. One example of such a configuration is if the dimensions of the top die of the stacked die configuration are approximately the same as or larger than the bottom die. In this case, spaces cannot be provided to singulate the stacked die. An alternative IDAC is used for such configurations.

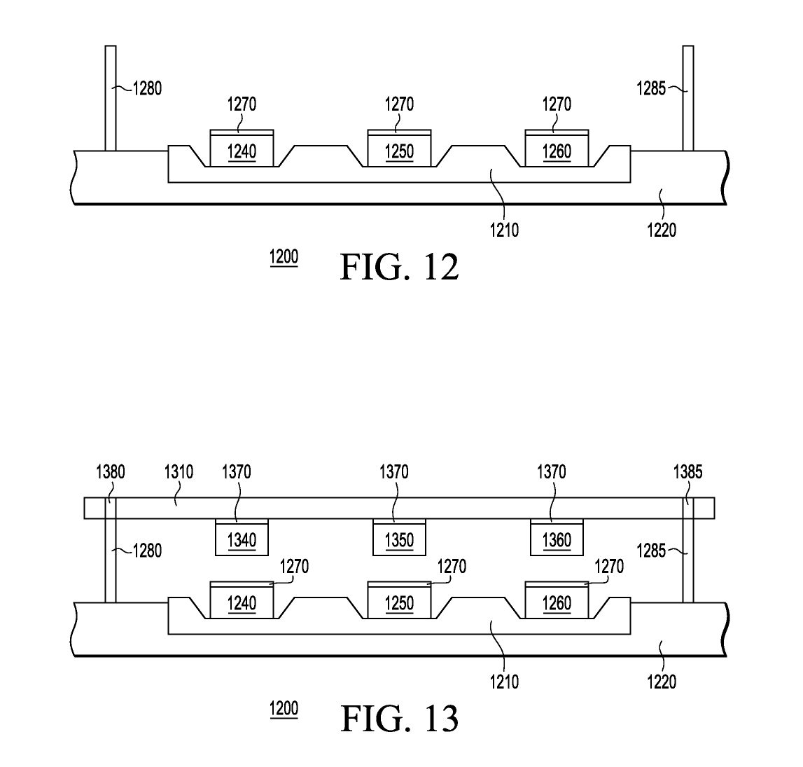

FIG. 12 is a simplified block diagram of a cross-section of a strip chuck embodiment of an IDAC, in accord with an alternate embodiment of the present invention. A portion of an IDAC wafer 1210 (as formed using techniques similar to those described above), is placed in an opening provided in strip chuck 1220. As with the wafer IDAC, pockets 1230 are provided in which die 1240, 1250, and 1260 can be placed. The die are provided to the strip chuck IDAC using a pick and place machine such as a high throughput die sorter. Each of the die can be laminated with an adhesive layer 1270 (applied prior to die singulation). Strip chuck 1220 also has alignment pins 1280 and 1285. In this embodiment, die 1240, 1250, and 1260 will be the top die for the stacked SIP devices. As will be discussed more fully below, strip chuck 1220 can provide openings for a plurality of IDAC wafer portions 1210.

FIG. 13 is a simplified block diagram illustrating a cross section of system 1200 at a stage in processing subsequent to FIG. 12, in accord with embodiments of the present invention. A package substrate 1310 is provided to strip chuck 1220. Bottom die 1340, 1350, and 1360 are adhesively attached to package substrate 1310 by means of adhesive layer 1370. As discussed above, selection of the materials for package substrate 1310 and adhesive layer 1370 are dependent upon the nature of the application. The package substrate is aligned to the strip chuck using alignment holes or features 1380 and 1385 and alignment pins 1280 and 1285.

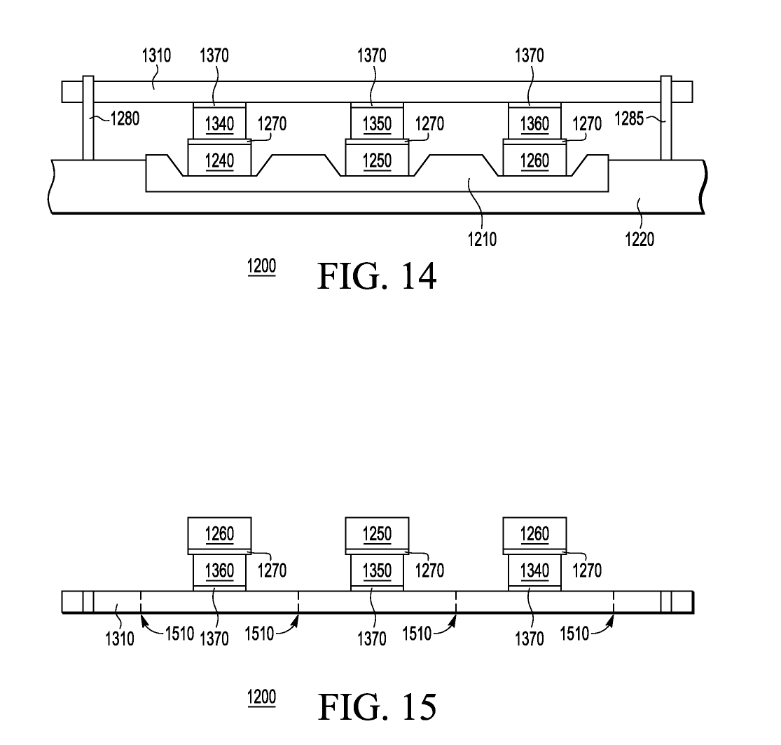

FIG. 14 is a simplified block diagram illustrating a cross section of system 1200 at a stage in processing subsequent to FIG. 13, in accord with embodiments of the present invention. At this stage, bottom die 1340, 1350, and 1360 are brought into contact with top die 1240, 1250, and 1260, respectively, by lowering the substrate/die assembly. At this point, adhesive layer 1270 joins the top and bottom die. A combination of pressure and heat can be applied to cure adhesive layer 1270.

As with the wafer IDAC embodiment, a plurality of stacked die assemblies can be formed using one adhesive contact/curing step, rather than individual contact/curing steps found in traditional methods. Again, significant time and accuracy gains can be realized by such a batch processing method.

FIG. 15 is a simplified block diagram of a cross section of the package substrate with the attached stacked die assemblies upon removal from the strip chuck, in accord with embodiments of the present invention. As illustrated, the dimensionally larger die 1240, 1250, and 1260 are the top die over die 1340, 1350, and 1360, respectively. Singulation lines 1510 where package substrate 1310 can be sawn to separate the assemblies are illustrated.

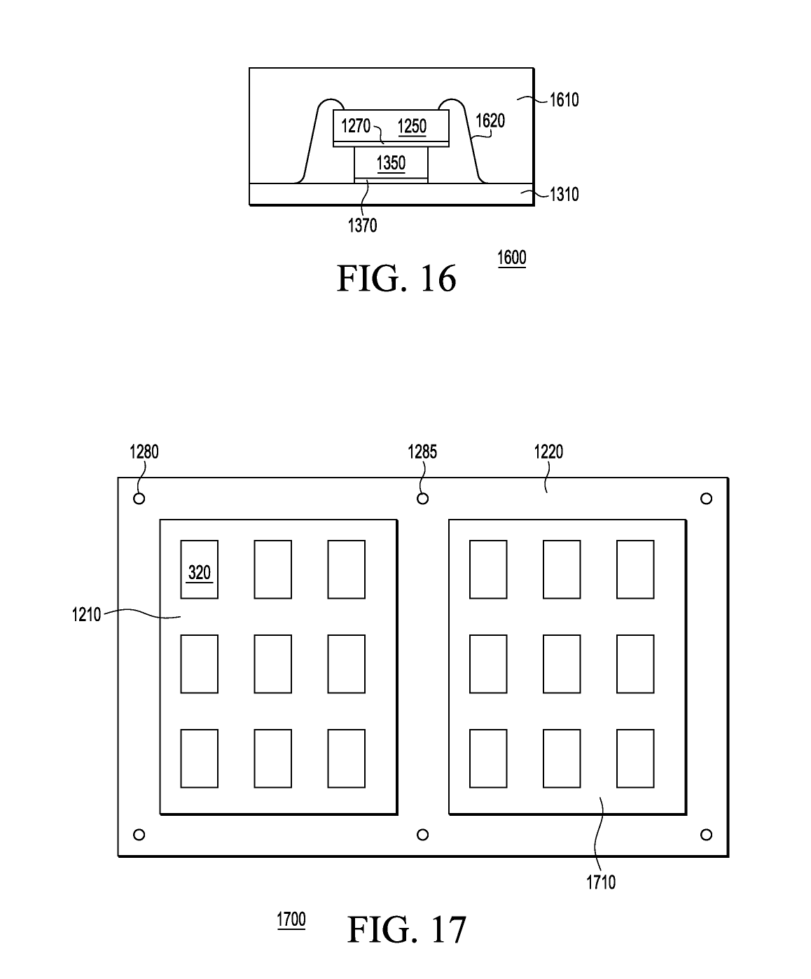

FIG. 16 is a simplified block diagram of a cross section of a singulated SIP 1600 formed in accord with embodiments of the present invention. A molding compound was applied to the structures affixed to substrate 1310 (e.g., bottom die 1250, top die 1350, and wire bonds 1620), forming an encapsulant 1610 encapsulating the structures within the molding material and formed a panel. As with the above embodiment, the molding material can be any appropriate encapsulant including, for example, silica-filled epoxy molding compounds, plastic encapsulation resins, and other polymeric materials such as silicones, polyimides, phenolics, and polyurethanes. Once the molding material is applied, the panel can be cured by exposing the materials to certain temperatures for a period of time, or by applying curing agents, or both. FIG. 16 illustrates SIP 1600 subsequent to singulating the encapsulated devices from the cured panel.

FIG. 17 is a top view of strip chuck IDAC 1700, as formed in accord with embodiments of the present invention. Portions of a wafer IDAC 1210 and 1710 are illustrated with a pattern of pockets 1230 formed thereon. The pattern of pockets can be determined through the use of the photolithographic methods discussed above. X and Y pitches can be determined based upon size and spacing of the die desired, as discussed above. Again, through the use of a silicon wafer and photolithographic methods, a great deal of flexibility is provided in formation of the IDAC. As discussed above, IDAC formation is not limited to use of a silicon wafer and etching techniques, as micro machining of other materials can be used in the alternative.

A strip chuck 1220 is provided that includes openings in which the silicon wafer IDAC portions are inserted. These openings should fit the silicon wafer IDAC portions such that the IDAC portions maintain accurate placement. Alignment features (e.g., 1280 and 1285) are also provided so that the package substrate can be accurately placed on the strip chuck for assembling the stacked packages, as described above.

Through the use of embodiments of the present invention, significant processing advantages for stacked semiconductor device package assembly can be realized. For example, using conventional stacked semiconductor device package assembly methods, it can take as long as seven hours to perform die attachment for 17,000 stacked assemblies. This involves a die-by-die assembly involving bonding and curing each die individually, and includes inherent rotational and lateral inaccuracies, as discussed above. Through the use of embodiments of the present invention, a high speed die sorting machine can be used to place the die in the disclosed IDACs. Then all of those placed die can be bonded to counterpart die, either in the form of a wafer or a substrate/die assembly, in the same step. It is estimated that this process will take approximately 2.5 hours for 17,000 stacked assemblies. Thus, as much as a 3× improvement in speed of assembly can be realized, increasing the number of stacked die assemblies that can be made in any unit of time.

Not only are speed improvements realized by embodiments of the present invention, but also the accuracy of the placement of the stacked die. The IDACs hold the die in place for assembly as determined by the accurate formation of the IDACs. This accuracy includes both rotational and lateral placement. Manufacture of a silicon IDAC through the use of photolithographic means provides a well-understood mechanism for maintaining the desired accuracy. Further, use of silicon wafers to form the IDACs is cost effective in the context of semiconductor device manufacturing.

By now it should be appreciated that there has been provided, in one embodiment, a method for packaging an electronic device assembly that includes placing a plurality of first semiconductor dies onto an intermediate die attach carrier (IDAC), where the IDAC has a plurality of pockets on one surface of the IDAC and each of the first semiconductor die is placed in a corresponding pocket. Each of the placed plurality of first semiconductor dies are attached to a corresponding second semiconductor die. This attaching is performed while the first semiconductor dies remain placed in the IDAC pockets and forms stacked die assemblies.

In one aspect of the above embodiment, the IDAC is formed such that each pocket is configured to dimensionally limit rotational and lateral freedom of motion of a die placed in the pocket. In a further aspect, each pocket provides less than two degrees of rotational freedom of motion and plus or minus 50 μm of lateral freedom of motion.

In another further aspect, forming the IDAC includes forming a photoresist layer on a silicon wafer, patterning the photoresist layer to provide top dimensions of the pockets, and etching the silicon wafer to provide a bottom dimension of the pockets that results in the limited rotational and lateral freedoms of motion. In still a further aspect, the etching includes performing an anisotropic etch.

In another further aspect, a second semiconductor device die wafer is provided that includes each of the second semiconductor device die, the second semiconductor device die wafer is singulated after the attaching discussed above, thus forming stacked die regions. Each stacked die region includes at least one of the first semiconductor device dies bonded to a portion of the second semiconductor device die wafer, and that portion is the second semiconductor device die. In still a further aspect, the process includes laminating a die attach adhesive on a first semiconductor device die wafer, and singulating the laminated first semiconductor device die wafer to form the plurality of first semiconductor device dies. The laminating and singulating are performed prior to the placing. In yet a further aspect, the placing of the first semiconductor device dies is performed using a die sorting device.

In another further aspect, the attaching of the placed first semiconductor device dies to the second semiconductor device die wafer includes aligning the second semiconductor device die wafer to the IDAC using alignment features on one or more of the second semiconductor device die wafer and the IDAC, applying pressure to the second semiconductor device die wafer while the second semiconductor device die wafer contacts the first semiconductor device die, and curing the die attach adhesive.

In another aspect, forming the IDAC includes forming the IDAC in one or more portions, and placing a first portion of the IDAC in an opening provided on a strip chuck, wherein the opening on the strip chuck dimensionally limits the rotational and lateral freedom of motion of the first portion of the IDAC. In a further aspect, the first portion of the IDAC is a rectilinear polygon.

In another further aspect, attaching the placed plurality of first semiconductor device dies to the corresponding second semiconductor device die includes mounting each of the second semiconductor device die on a package substrate, aligning the package substrate to the IDAC using alignment features on the package substrate and the strip chuck, applying pressure to the package substrate while the second semiconductor device die contact the first semiconductor device die, and curing die attach adhesive laminated on one of the first semiconductor device die or the second semiconductor device die.

Another aspect of the above embodiment is a semiconductor device package formed using the method described. In a further aspect, the first or second semiconductor device die is a MEMS device.

Another embodiment of the present invention provides an intermediate die attach carrier (IDAC) including a body having first and second major surfaces, a plurality of pockets formed on the first major surface of the body, where each pocket of the plurality of pockets is dimensionally configured to provide limited lateral and rotational freedom of motion to a first semiconductor device die placed in the pocket, and the IDAC is configured to hold a corresponding first semiconductor device die in each of the plurality of pockets during a die attach process in which each of the corresponding first semiconductor device die are adhesively coupled to a corresponding second semiconductor device die.

In one aspect of the above embodiment, the body of the IDAC includes a silicon wafer, and the plurality of pockets are formed by a process including forming a photoresist layer on the silicon wafer, patterning the photoresist layer, and etching the silicon wafer. The patterning provides openings in the photoresist to provide top dimensions of the plurality pockets. The etching provides a bottom dimension of the pockets resulting in the limited rotational and lateral freedoms of motion. In another aspect of the above embodiment, the etching is an anisotropic etch. In another further aspect, the limited lateral freedom of motion is plus or minus 50 μm and the limited rotational freedom of motion is less than 2 degrees.

In another aspect of the above embodiment, the IDAC is further configured to be placed in an opening provided on a strip chuck, and the opening on the strip chuck dimensionally limits rotational and lateral freedom of motion of the IDAC. In a further aspect, the IDAC is a rectilinear polygon.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, the IDAC can be made from a variety of materials and can provide a variety of die pockets in a variety of configurations. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method for packaging an electronic device assembly, the method comprising:
placing a plurality of first semiconductor device dies onto an intermediate die attach carrier (IDAC), wherein
the IDAC comprises a plurality of pockets on a major surface of the IDAC, each first semiconductor device die is placed in a corresponding pocket; and
attaching each of the placed plurality of first semiconductor device dies to a corresponding second semiconductor device die, wherein
said attaching is performed while the first semiconductor device dies remain placed on the IDAC pockets, and
said attaching forms corresponding stacked die assemblies.

2. The method of claim 1 further comprising:
forming the IDAC such that each pocket is configured to dimensionally limit rotational and lateral freedom of motion of a first semiconductor device die placed in the pocket.

3. The method of claim 2 wherein each pocket provides less than 2 degree rotational freedom of motion and +/−50 μm lateral freedom of motion.

4. The method of claim 2 wherein said forming the IDAC comprises:
forming a photoresist layer on a silicon wafer;
patterning the photoresist layer, wherein said patterning provides openings configured to provide top dimensions of the plurality of pockets; and
etching the silicon wafer to provide a bottom dimension of the pockets resulting in the limited rotational and lateral freedom of motion.

5. The method of claim 4 wherein said etching comprises performing an anisotropic etch.

6. The method of claim 4 further comprising:
providing a second semiconductor device die wafer comprising each of the second semiconductor device die;
singulating the second semiconductor device die wafer subsequent to said attaching in order to form stacked die regions, wherein
each stacked die region comprises at least one of the first semiconductor device dies bonded to a portion of the second semiconductor device die wafer, and
the portion of the second semiconductor device die wafer is the second semiconductor device die.

7. The method of claim 6 further comprising:
laminating a die attach adhesive on a first semiconductor device die wafer;
singulating the laminated first semiconductor device die wafer to form the plurality of first semiconductor device dies, wherein
said laminating and singulating are performed prior to said placing.

8. The method of claim 7 wherein said placing the plurality of first semiconductor device dies is performed using a die sorting device.

9. The method of claim 7 wherein said attaching the placed plurality of first semiconductor device dies to the second semiconductor device die wafer comprises:
aligning the second semiconductor device die wafer to the IDAC using alignment features on one or more of the second semiconductor device die wafer and the IDAC;
applying pressure to the second semiconductor device die wafer while the second semiconductor device die wafer contacts the first semiconductor device die; and
curing the die attach adhesive.

10. The method of claim 2 wherein said forming the IDAC further comprises:
forming the IDAC in one or more portions;
placing a first portion of the one or more potions of the IDAC in an opening provided on a strip chuck, wherein the opening on the strip chuck dimensionally limits rotational and lateral freedom of motion of the first potion of the IDAC.

11. The method of claim 10 wherein the first portion of the IDAC is a rectilinear polygon.

12. The method of claim 10 wherein said attaching the placed plurality of first semiconductor device dies to the corresponding second semiconductor device die comprises:
mounting each of the second semiconductor device die on a package substrate;
aligning the package substrate to the IDAC using alignment features on the package substrate and the strip chuck;
applying pressure to the package substrate while the second semiconductor device die contact the first semiconductor device die; and
curing die attach adhesive laminated on one of the first semiconductor device die or the second semiconductor device die.

13. A semiconductor device package formed using the method of claim 1.

14. The semiconductor device package of claim 13 wherein one of the first semiconductor device die or the second semiconductor device die is a microelectromechanical system device.

15. An intermediate die attach carrier comprising:
a body having first and second major surfaces;
a plurality of pockets formed on the first major surface of the body, wherein
each pocket of the plurality of pockets is dimensionally configured to provide limited lateral and rotational freedom of motion to a first semiconductor device die placed in the pocket, and
the intermediate die attach carrier (IDAC) is configured to hold a corresponding first semiconductor device die in each of the plurality of pockets during a die attach process in which each of the corresponding first semiconductor device die are adhesively coupled to a corresponding second semiconductor device die.

16. The intermediate die attach carrier of claim 15, wherein
the body comprises a silicon wafer; and
the plurality of pockets are formed by a process comprising
forming a photoresist layer on the silicon wafer,
patterning the photoresist layer, wherein said patterning provides openings configured to provide top dimensions of the plurality of pockets, and
etching the silicon wafer to provide a bottom dimension of the pockets resulting in the limited rotational and lateral freedom of motion.

17. The intermediate die attach carrier of claim 16 wherein said etching comprises an anisotropic etch.

18. The intermediate die attach carrier of claim 15 wherein the limited lateral freedom of motion is +/−50 μm and rotational freedom of motion is less than 2 degrees.

19. The intermediate die attach carrier of claim 15 wherein
the IDAC is further configured to be placed in an opening provided on a strip chuck, and
the opening on the strip chuck dimensionally limits rotational and lateral freedom of motion of the IDAC.

20. The intermediate die attach carrier of claim 19 wherein the IDAC comprises a rectilinear polygon.
